(19) United States
(12) Patent Application Publication
(10) Pub. No.: US 2008/0179618 A1
(43) Pub. Date: Jul. 31, 2008

(54) CERAMIC LED PACKAGE

(76) Inventor: CHING-TAI CHENG, Hsinchu City (TW)

Correspondence Address: PATTERSON & SHERIDAN, L.L.P., 3040 POST OAK BOULEVARD, SUITE 1500, HOUSTON, TX, 77056, US

(21) Appl. No.: 11/627,489

(22) Filed: Jan. 26, 2007

(51) Int. Cl. H01L 33/00; H05K 7/20

(52) U.S. Cl. 257/99; 361/707

(57) ABSTRACT

Light-emitting diode (LED) packages with improved heat transfer paths for LED dies encased therein when compared to conventional LED packages are provided. For some embodiments, the LED package includes a ceramic substrate having a top cavity with one or more LED dies disposed within and having a bottom cavity for receiving a metallic insert to dissipate heat away from the LED dies. For other embodiments, an LED package is provided that includes a ceramic substrate having a heat spreader coupled to thermal vias filled with a highly thermally conductive composite.

### BACKGROUND OF THE INVENTION

1. Field of the Invention

Embodiments of the present invention generally relate to the field of light-emitting diode (LED) technology and, more particularly, to LED packaging.

2. Description of the Related Art

Heat transfer management is a concern for designers of light-emitting diodes (LEDs). When LEDs are driven with high currents, high device temperatures may occur because of insufficient heat transfer from the p-n junction of the semiconductor die to the ambient environment. Such high temperatures may harm the semiconductor and lead to such degradations as accelerated aging, separation of the LED die from the lead frame, and breakage of bond wires.

In addition to the aforementioned problems, the optical properties of the LED vary with temperature, as well. As an example, the light output of an LED typically decreases with increased junction temperature. Also, the emitted wavelength can change with temperature due to a change in the semiconductor bandgap energy.

The main path for heat dissipation (thermal path) in LED devices encased in ceramic packages 1,2 of the prior art, as shown in FIG. 1, is from the p-n junction of one or more LED dies 3 to the lead frame 4a,4b and then through the ends of the leads via heat conduction. At the ends of the leads, heat conduction, convection and radiation serve to transfer heat away from the LED when mounted on a printed circuit board (PCB), for example. There is also a secondary path of heat conduction from the surfaces of the semiconductor dies 3 to surfaces of the ceramic package 1,2. The problem with this design is that the majority of the lead frame 4a, 4b is situated within the ceramic package 1,2, which acts as a thermal insulator, and the main path for heat dissipation out of the device is limited by the size of the leads. Even designs that have added to the size or number of leads in an effort to promote heat transfer still possess an inherent bottleneck for heat dissipation, as the leads are still sandwiched in the thermally insulative ceramic package.

Other conventional LED device designs have added electrically conductive thermal vias disposed in a bottom portion of the ceramic package underneath the LED dies, so that heat may be transferred from the LED dies through the growth substrate (e.g., sapphire, silicon carbide, and gallium arsenide) and the thermal vias to a PCB, heat sink, or other suitable entity on which the LED device is mounted. However, the insulative properties of the growth substrate limit the potential heat dissipation. Furthermore, if the LED dies are vertical light-emitting diode (VLED) dies having LED stacks disposed above a metal substrate, the electrically conductive thermal vias make electrical contact with the metal substrate, thereby decreasing the flexibility of the circuit layout

Accordingly, what is needed is a technique to packaging LEDs that improves heat dissipation, preferably without limiting the circuit layout flexibility.

### SUMMARY OF THE INVENTION

One embodiment of the present invention provides a packaged light-emitting diode (LED) device. The packaged LED device generally includes a ceramic substrate having a top cavity and a bottom cavity; one or more LED dies coupled to a plurality of connection pads, the connection pads being disposed within the top cavity of the ceramic substrate and coupled by electrical vias to terminals for external connection; and a metallic insert disposed within the bottom cavity of the ceramic substrate for conducting heat away from the LED dies.

Another embodiment of the present invention provides a package for at least partially encasing one or more LED dies. The package generally includes a ceramic substrate having a cavity underneath an area designated for the LED dies; and a thermally conductive insert disposed within the cavity for conducting heat away from the LED dies.

Yet another embodiment of the present invention provides a packaged LED device. The packaged LED device generally includes a ceramic substrate having an upper portion and a lower portion; a plurality of connection pads disposed within a cavity of the ceramic substrate's upper portion and coupled by electrical vias to terminals for external connection; and one or more LED dies coupled to the plurality of connection pads and disposed within the cavity, wherein a plurality of thermal vias comprised of a composite are provided in the ceramic substrate's lower portion for conducting heat away from the LED dies.

Yet another embodiment of the present invention provides a ceramic substrate for at least partially encasing one or more LED dies. The ceramic substrate generally includes an upper portion having a cavity for disposing the LED dies therein and a lower portion providing a plurality of thermal vias comprised of a composite for conducting heat away from the LED dies.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a prior art cross-sectional schematic representation of a light-emitting diode (LED) device having a ceramic package;

FIGS. 2A-C illustrate a packaged LED device comprising a multilayered ceramic package, multiple LED dies, and a metallic insert when viewed from two different perspectives and in cross section in accordance with an embodiment of the invention;

FIGS. 3A-C illustrate a packaged LED device comprising a multilayered ceramic package, multiple LED dies, a heat spreader, and thermal vias when viewed from two different perspectives and in cross section in accordance with an embodiment of the invention;

FIG. 4 portrays composite material composed of silver and reinforcing material for a thermal via in accordance with an embodiment of the invention;

FIG. 5 portrays composite material composed of alumina-coated silver powder for a thermal via in accordance with an embodiment of the invention; and

FIG. 6 portrays composite material composed of a mixture of silver and alumina for a thermal via in accordance with an embodiment of the invention.

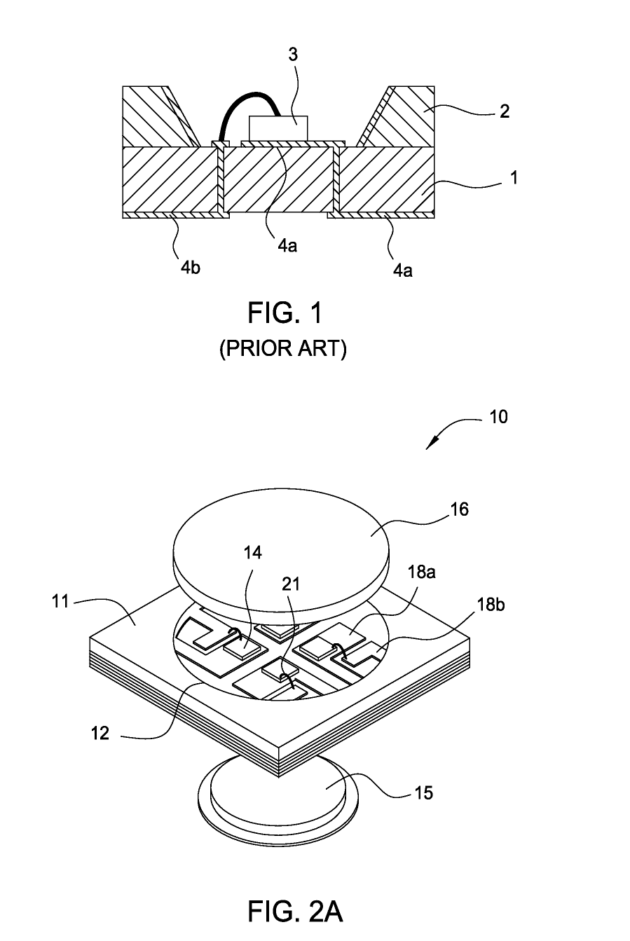

### DETAILED DESCRIPTION

Embodiments of the present invention provide light-emitting diode (LED) packages with improved heat transfer paths for LED dies encased therein when compared to conventional LED packages. For some embodiments, the LED package includes a ceramic substrate having a top cavity with one or more LED dies disposed within and having a bottom cavity for receiving a metallic insert to dissipate heat away from the LED dies. For other embodiments, an LED package is provided that includes a ceramic substrate having a heat spreader coupled to thermal vias filled with a highly thermally conductive composite.

### An Exemplary LED Package

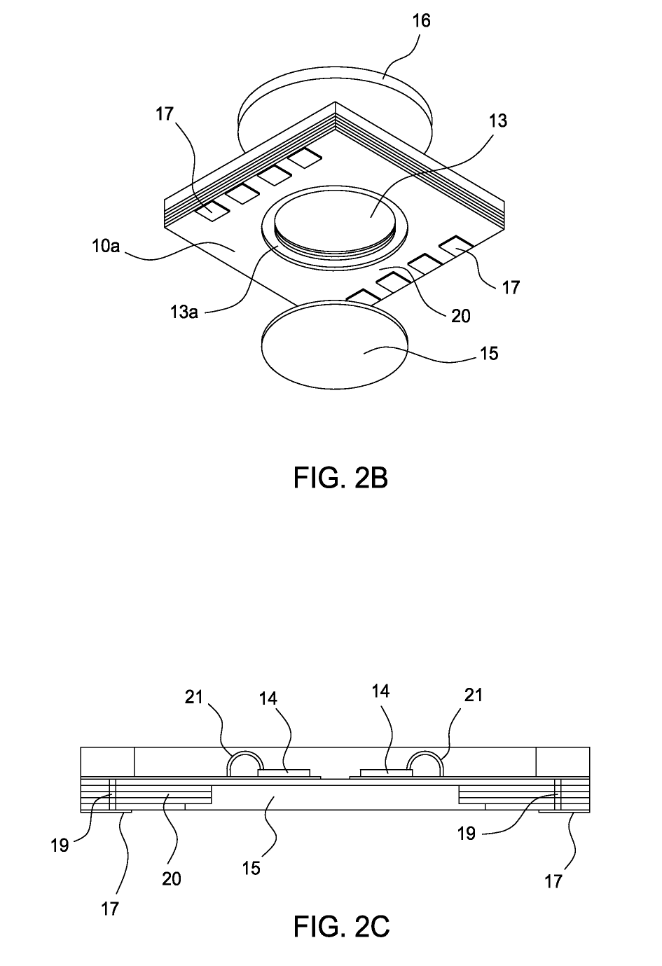

FIGS. 2A-B illustrate various components of an LED package 10 when viewed from two different perspectives according to one embodiment of the invention. The LED package 10 may comprise a multilayered ceramic substrate 11 having a top cavity 12 and a bottom cavity 13. Within the top cavity 12, one or more LED dies 14 may be disposed on connection pads 18a. Depending on the desired arrangement of the LED dies, for example, the top cavity 12 may be substantially circular, rectangular, or any other suitable shape. The LED dies 14 may be sealed within the top cavity 12 and protected by filling the cavity 12 with any suitable material to form a cover 16. Typically, the cover 16 is optically transparent, but for some embodiments, the cover 16 may be translucent or opaque. For an optically transparent cover 16, materials such as epoxy, silicone, polyurethane, or other clear material(s) may be employed. Such optically transparent materials may contain phosphorus for some embodiments in an effort to alter the emitted light wavelength of the LED device.

For some embodiments, the ceramic substrate 11 may provide a space similar to the top cavity 12 to house the LED dies 14, but the substrate 11 itself or a separate cover may fully cover this space and the LED dies 14 disposed within, thereby blocking light emitted from the LED dies. This type of LED package may be used for applications that do not require light emission, but call for one of the other specified electrical characteristics of the LED device.

For external electrical connection, one type of doped region (p-doped or n-doped) of the LED dies 14 may be attached to the connection pads 18a by any suitable adhesive, such as conductive epoxy, solder, a eutectic bonding layer, and the like. Thus, this type of doped region of the LED dies 14 may be electrically and potentially thermally coupled to the connection pads 18a, which, in turn, may be electrically coupled to surface mount terminals 17 located on the bottom surface 10a of the LED package 10 by electrical vias 19, as shown in FIGS. 2B-C. The terminals 17 may be composed of any suitable electrically conductive material, such as silver palladium (AgPd). Bonding wires 21 may connect the other type of doped region (n-doped or p-doped) of the LED dies 14 to the connection pads 18b. The bonding wires 21 may be composed of any suitable electrically conductive, reliable, and malleable metal, such as gold and aluminum. The connection pads 18b may also be electrically coupled to other surface mount terminals 17 by electrical vias 19. For a vertical light-emitting diode (VLED) die, for example, the p-doped layer may be disposed above a metal substrate, and the metal substrate may be attached to the connection pad 18a. The n-doped layer, which may be disposed above an active layer for light emission and, more specifically, a contact coupled to the n-doped layer may be coupled to the connection pad 18b via the bonding wire 21.

For embodiments with a eutectic layer, materials—such as Sn, In, Pb, AuSn, CuSn, AgIn, CuIn, SnPb, SnInCu, SnAgIn, SnAg, SnZn, SnAgCu, SnZnBi, SnZnBiIn, and SnAgInCu—may couple the LED dies 14 (or, more specifically, a metal substrate of the LED dies) with the connection pads 18a. The use of a eutectic layer may allow for eutectic bonds having high bonding strength and good stability at a low process temperature to form between LED dies 14 and the connection pads 18a during fabrication of the LED device, as disclosed in commonly owned U.S. patent application Ser. No. 11/382,296, filed May 9, 2006, entitled “Vertical LED with Eutectic Layer,” herein incorporated by reference. Also, eutectics have a high thermal conductivity and a low coefficient of thermal expansion, which may lead to a decreased overall thermal resistance between the LED dies 14 and the ambient environment.

As for the ceramic substrate 11, it may be composed of layers of green ceramic tape. This green tape may be fabricated from ceramic powders of materials such as alumina (Al₂O₃), aluminum nitride (AlN), or glass-ceramic, which may be mixed with organic binders and a solvent. The resulting mixture may be cast and cut to form the ceramic tape. Circuit patterns, such as the connection pads 18a-b, may be created by screen printing on one or more tape layers. Vias may be subsequently punched in the tape and filled with a conductor ink in order to connect the circuit patterns of different tape layers. The tapes may then be aligned, laminated, and fired to remove the organic materials and to sinter the metal patterns and ceramic tape layers, thereby forming a low temperature co-fired ceramic (LTCC) substrate. The sintering profile may be dependent on the composition of the ceramic powders in the green tape layers. For example, 800-900° C. may be employed for sintering glass-ceramic, while alumina and aluminum nitride may be sintered at 1500-1800° C.

The bottom cavity 13 of the ceramic substrate 11 is illustrated in FIG. 2B according to one embodiment of the invention. The depth of the bottom cavity 13 may extend from the bottom surface 10a of the LED package 10 to a layer of the multilayered ceramic substrate 11 just beneath the LED dies 14, as shown in the cross section of FIG. 2C. The bottom cavity 13 may be designed to receive a metallic insert 15 in an effort to provide improved heat dissipation away from the LED dies 14 when compared to conventional ceramic packages. Composed of any suitable thermally and electrically conductive material (e.g., copper, aluminum, and copper plated with gold, silver, or beryllium, for example, in an effort to prevent oxidation), the metallic insert 15 may be attached to the ceramic substrate 11 via any suitable means, such as solder or an adhesive. The attachment may occur at a portion of the ceramic substrate 11 just beneath the LED dies 14 and/or along a ridge 13a formed by countersinking the bottom cavity 13 (see FIG. 2B).

By having the bottom surface of the metallic insert 15 exposed at and flush with the bottom surface 10a of the ceramic substrate 11, the metallic insert 15 may act as a heat sink when the LED package 10 is surface mounted to a pad of a printed circuit board (PCB), for example. The size of the bottom cavity 13 and the corresponding metallic insert 15 may preferably be as large as possible within the confines of the ceramic substrate 11 in an effort to dissipate increased amounts of heat away from the LED dies 14 when compared to conventional ceramic LED packages. Some insulative material 20 should remain between the metallic insert 15 and the terminals 17 in an effort to prevent electrical shorting. Although the metallic insert 15 depicted in FIGS. 2A-B has a round shape, other shapes (e.g., square or rectangular) for the metallic insert and the receptive bottom cavity may be desired. This shape may be dependent on the arrangement of the LED dies 14 above the bottom cavity 13.

Even though only one bottom cavity 13 for receiving a single metallic insert 15 is depicted in FIGS. 2A-C, those skilled in the art will recognize that embodiments of the LED package with multiple bottom cavities, each receiving a metallic insert, is within the scope of the invention. These multiple bottom cavities and their corresponding metallic inserts may have the same or different shapes.

The thermal resistance (θ) of a substrate or package underneath the LED dies may be approximated by θ=t/kA, where t is the thickness of the package below the LED dies usually on the order of μm, k is the thermal conductivity of the package in W/m·K, and A is the area of the package below the LED dies. Table I below illustrates the calculation of the thermal resistance for LED packages composed solely of low temperature co-fired ceramics (LTCC) or alumina with a nominal thickness t and a nominal package area A according to the prior art in the first two rows. In the third row, the thermal resistance of an LED package having a copper (Cu) metallic insert (with a thickness 8/10 of the nominal thickness t) soldered within the bottom cavity 13 of an LTCC substrate according to one embodiment of the invention is calculated.

TABLE I

| | | | Thermal | |
|---|---|---|---|---|
| | Material of | Thickness of | conductivity of | Thermal |
| | substrate | substrate | substrate | Resistance |
| Prior invention | LTCC* | t | 3 | $\frac{t}{3 A} ( 0.33 t / A )$ |
| | Alumina | t | 20 | $\frac{t}{20 A} ( 0.05 t / A )$ |
| Present invention | LTCC*, Cuand Solder | 1/10t for LTCC8/10t for Cu1/10t for solder | 3, 400 and80 | $\begin{matrix}\frac{\frac{1}{10} t}{3 A} + \frac{\frac{8}{10} t}{400 A} + \frac{\frac{1}{10} t}{80 A} \\ ( 0.037 t / A )\end{matrix}$ |

*Low Temperature Cofired Ceramics

From Table I, the thermal resistance (0.037 t/A) of the LED package 10 according to an embodiment of the present invention is significantly lower than the thermal resistance of the LTCC package (0.33 t/A) and the alumina package (0.05 t/A) of the prior art. This reduction may be attributed to the metallic insert 15 (and to a lesser degree, to the solder) with a higher thermal conductivity than the LTCC or alumina placed underneath the LED dies in the prior art. Having a lower thermal resistance should allow the LED package described herein to dissipate more heat away from the p-n junctions of the LED dies compared to conventional LED packages.

### Another Exemplary LED Package

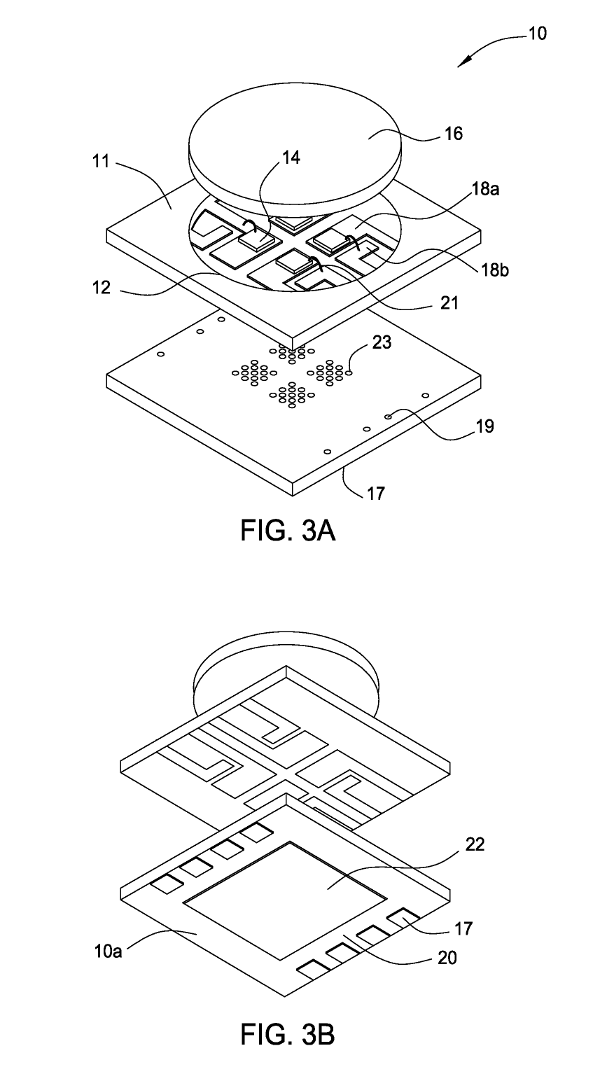

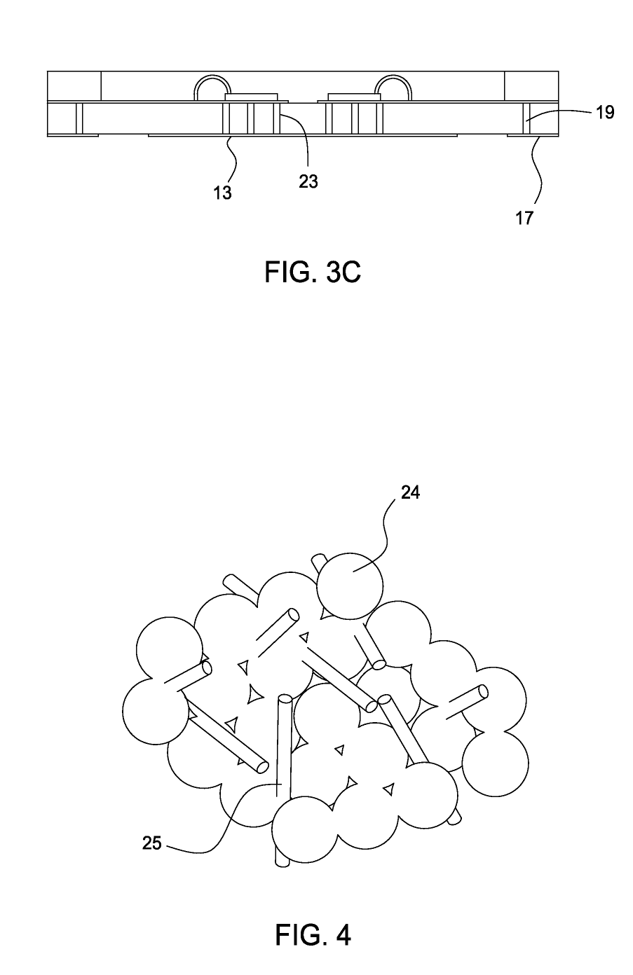

Another embodiment of an LED package 10 is illustrated in FIGS. 3A-C. As described herein, the LED package 10 may include a multilayered ceramic substrate 11 having a top cavity 12. Within the top cavity 12, one or more LED dies 14 may be disposed on connection pads 18a. The LED dies 14 may be sealed within the top cavity 12 and protected by filling the cavity 12 with any suitable material to form a cover 16. The connection pads 18a-b may be electrically coupled to surface mount terminals 17 located on the bottom surface 10a of the LED package 10 by electrical vias 19. Bonding wires 21 may connect the LED dies 14 with the connection pads 18b.

Rather than the metallic insert 15, the embodiment of the invention shown in FIGS. 3A-C employs thermal vias 23 disposed within a bottom portion of the ceramic substrate 11 underneath the LED dies 14. The thermal vias 23 may extend from the bottom surface 10a of the LED package 10 to a layer of the multilayered ceramic substrate 11 just beneath the LED dies 14, as shown in the cross section of FIG. 3C. The thermal vias 23 may be coupled to a heat spreader 22 in an effort to provide improved heat dissipation away from the LED dies 14 when compared to conventional ceramic packages. Comprising any suitable thermally and electrically conductive material, such as silver palladium (AgPd), the heat spreader 22 may be attached to the bottom surface 10a of the LED package 10 via any suitable means, such as solder or an adhesive.

By having the bottom surface of the heat spreader 22 exposed at and flush with the bottom surface 10a of the ceramic substrate 11, the heat spreader 22 may act as a heat sink when the LED package 10 is surface mounted to a pad of a printed circuit board (PCB), for example. The size of the heat spreader 22 and the number of thermal vias 23 may preferably be as large as possible within the confines of the ceramic substrate 11 in an effort to dissipate increased amounts of heat away from the LED dies 14 when compared to conventional ceramic LED packages. Some insulative material 20 should remain between the heat spreader 22 and the terminals 17 in an effort to prevent electrical shorting. Although the heat spreader 22 and corresponding arrangement of thermal vias 23 depicted in FIGS. 3A-B have a square shape, other shapes (e.g., round or rectangular) for the heat spreader and the arrangement of thermal vias may be desired. These shapes may be dependent on the arrangement of the LED dies 14 above.

During fabrication of the LED package 10, holes for the thermal vias 23 may be filled with a composite having high thermal conductivity such that embodiments of the invention may have thermal vias with decreased thermal resistance and hence, increased heat dissipation away from the LED dies 14 when compared to conventional LED packages. For some composites described herein, the thermal conductivity may be as high as 430 W/m·K.

Referring now to FIG. 4, for some embodiments, holes for the thermal vias 23 may be filled with a composite paste composed of silver powder 24, reinforcement 25, organic binders, and a solvent. The reinforcement 25 may be any suitable means of providing structural rigidity to the composite, such as vapor grown carbon fiber (VGCF) or carbon nanotubes (CNTs). VGCF exhibits thermal conductivities unsurpassed by other carbon fibers due to its highly graphitic nature, and with a tensile strength 10 times greater than steel at about one quarter the weight, CNTs may be considered the strongest known material for their weight. The thermal conductivity of the resulting composite silver, although highly dependent on the content and amount of the reinforcement 25, is typically higher than that of pure silver.

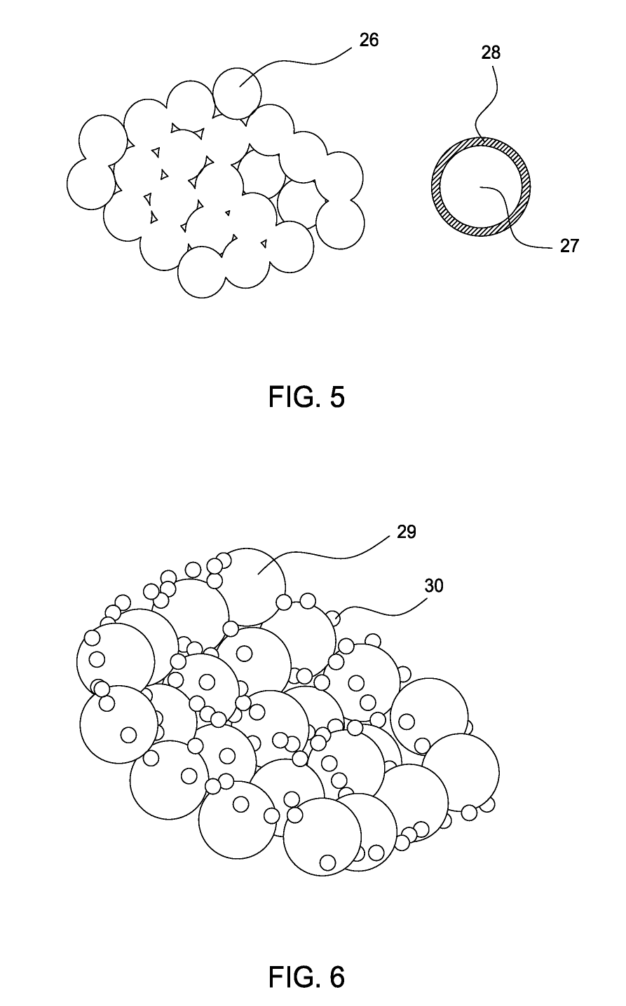

Referring now to FIG. 5, for other embodiments, holes for the thermal vias 23 may be filled with a paste of alumina-coated silver powder 26. The paste may be made from silver powder 27 and alkylacetoacetate aluminum di-isopropylate, which may be mixed with organic binders and a solvent. After sintering, the alkylacetoacetate aluminum di-isopropylate may coat the silver powder to form silver powder 27 surrounded by an alumina layer 28. Such a composite may possess a high thermal conductivity and a high electrical resistance.

For other embodiments, the thermal vias 23 may be composed of a mixture of alumina 29 and silver powder 30, as shown in FIG. 6. Again, such a mixture may possess a high thermal conductivity, which may lead to enhanced heat dissipation when used for thermal vias in LED packages according to embodiments of the invention when compared to conventional LED packages.

Embodiments of the LED packages described herein may enjoy another advantage over conventional LED packages. Because the thermal path, whether through a metallic insert or thermal vias to a heat spreader, may be separated from the electrical connections, the arrangement of the LED dies and/or other desired circuitry (e.g., connection pads and electrical vias) may retain a greater degree of circuit design flexibility over conventional LED packages where the electrical and thermal paths are the same.

While the foregoing is directed to embodiments of the present invention, other and further embodiments of the invention may be devised without departing from the basic scope thereof, and the scope thereof is determined by the claims that follow.

1. A packaged light-emitting diode (LED) device comprising:
a ceramic substrate having a top cavity and a bottom cavity;
one or more LED dies coupled to a plurality of connection pads, the connection pads being disposed within the top cavity of the ceramic substrate and coupled by electrical vias to terminals for external connection; and
a metallic insert disposed within the bottom cavity of the ceramic substrate for conducting heat away from the LED dies.

2. The LED device of claim 1, wherein the metallic insert is round.

3. The LED device of claim 1, wherein the metallic insert comprises at least one of copper, aluminum, and plated copper.

4. The LED device of claim 1, wherein the metallic insert is soldered or attached by adhesive to the ceramic substrate.

5. The LED device of claim 1, wherein the ceramic substrate comprises a low temperature co-fired ceramic (LTCC) substrate.

6. The LED device of claim 1, wherein the one or more LED dies are vertical light-emitting diode (VLED) dies comprising LED stacks disposed above a metal substrate.

7. The LED device of claim 1, wherein the top cavity is filled with an optically transparent material.

8. The LED device of claim 7, wherein the transparent material comprises at least one of epoxy, silicone, polyurethane.

9. The LED device of claim 7, wherein the transparent material contains phosphorus.

10. The LED device of claim 1, wherein the LED dies are coupled to the connection pads using at least one of solder, a conductive epoxy, and a eutectic layer.

11. The LED device of claim 10, wherein the eutectic layer comprises at least one of Sn, In, Pb, AuSn, CuSn, AgIn, CuIn, SnPb, SnInCu, SnAgIn, SnAg, SnZn, SnAgCu, SnZnBi, SnZnBiIn, and SnAgInCu.

12. A package for at least partially encasing one or more light-emitting diode (LED) dies, comprising:
a ceramic substrate having a cavity underneath an area designated for the LED dies; and
a thermally conductive insert disposed within the cavity for conducting heat away from the LED dies.

13. The package of claim 12, wherein the ceramic substrate comprises layers of green ceramic tape fabricated from ceramic powders selected from alumina (Al₂O₃), aluminum nitride (AlN), and glass-ceramic.

14. The package of claim 12, wherein the ceramic substrate comprises a low temperature co-fired ceramic (LTCC) substrate.

15. The package of claim 12, wherein the insert is round.

16. The package of claim 12, wherein the insert comprises metal.

17. The package of claim 12, wherein the insert is soldered or attached by adhesive to the ceramic substrate.

18. A packaged light-emitting diode (LED) device comprising:
a ceramic substrate having an upper portion and a lower portion;
a plurality of connection pads disposed within a cavity of the ceramic substrate's upper portion and coupled by electrical vias to terminals for external connection; and
one or more LED dies coupled to the plurality of connection pads and disposed within the cavity, wherein a plurality of thermal vias comprised of a composite are provided in the ceramic substrate's lower portion for conducting heat away from the LED dies.

19. The LED device of claim 18, wherein the thermal vias comprise a composite of silver and reinforcing material.

20. The LED device of claim 19, wherein the reinforcing material comprises vapor grown carbon fiber (VGCF) or carbon nanotubes (CNTs).

21. The LED device of claim 18, wherein the thermal vias comprise a mixture of alumina powder and silver powder.

22. The LED device of claim 18, wherein the thermal vias comprise a composite of alumina-coated silver.

23. The LED device of claim 18, wherein the ceramic substrate comprises a low temperature co-fired ceramic (LTCC) substrate.

24. The LED device of claim 18, wherein the one or more LED dies are vertical light-emitting diode (VLED) dies comprising LED stacks disposed above a metal substrate.

25. The LED device of claim 18, wherein the top cavity is filled with an optically transparent material.

26. The LED device of claim 25, wherein the transparent material comprises at least one of epoxy, silicone, polyurethane.

27. The LED device of claim 25, wherein the transparent material contains phosphorus.

28. The LED device of claim 18, wherein the LED dies are coupled to the connection pads using at least one of solder, a conductive epoxy, and a eutectic layer.

29. The LED device of claim 28, wherein the eutectic layer comprises at least one of Sn, In, Pb, AuSn, CuSn, AgIn, CuIn, SnPb, SnInCu, SnAgIn, SnAg, SnZn, SnAgCu, SnZnBi, SnZnBiIn, and SnAgInCu.

30. A ceramic substrate for at least partially encasing one or more light-emitting diode (LED) dies, comprising:
an upper portion having a cavity for disposing the LED dies therein; and
a lower portion providing a plurality of thermal vias comprised of a composite for conducting heat away from the LED dies.

31. The ceramic substrate of claim 30, wherein the thermal vias comprise a composite of silver and reinforcing material.

32. The ceramic substrate of claim 31, wherein reinforcing material comprises vapor grown carbon fiber (VGCF) or carbon nanotubes (CNTs).

33. The ceramic substrate of claim 30, wherein the thermal vias comprise a mixture of alumina powder and silver powder.

34. The ceramic substrate of claim 30, wherein the thermal vias comprise a composite of alumina-coated silver.

35. The ceramic substrate of claim 30, wherein connection pads for the LED dies are screen printed on a surface of the upper portion within the cavity.
